(19) United States
(12) Patent Application Publication
(10) Pub. No.: US 2025/0162450 A1
(43) Pub. Date: May 22, 2025

(54) APPARATUS, SYSTEM AND METHOD FOR PREDICTING STATE OF CHARGE OF BATTERY

(71) Applicants: Hyundai Motor Company, Seoul (KR); Kia Corporation, Seoul (KR)

(72) Inventors: Dae Gun JIN, Hwaseong-Si (KR); Woo Sung KIM, Hwaseong-Si (KR); Tae Woo KANG, Hwaseong-Si (KR)

(73) Assignees: Hyundai Motor Company, Seoul (KR); Kia Corporation, Seoul (KR)

(21) Appl. No.: 18/943,596

(22) Filed: Nov. 11, 2024

(30) Foreign Application Priority Data
Nov. 21, 2023 (KR) 10-2023-0162502

(51) Int. Cl. B60L 58/12

(52) U.S. Cl. CPC B60L 58/12; B60L 2260/54

(57) ABSTRACT

In a battery SOC prediction apparatus, system, and method, the battery SOC prediction apparatus includes: a processor configured to predict a state of charge (SOC) value of a battery in response to a case where a vehicle arrives at a destination according to energy expected to be consumed while driving to the destination, and in the instant case, to correct the SOC value of the battery upon arrival at the destination according to an electrical load and a battery temperature by predicting the electric load and the battery temperature according to a driving time of the vehicle; and a storage configured to store algorithms and data driven by the processor.

### CROSS-REFERENCE TO RELATED APPLICATION

The present application claims priority to Korean Patent Application No. 10-2023-0162502, filed on Nov. 21, 2023, the entire contents of which is incorporated herein for all purposes by this reference.

### BACKGROUND OF THE PRESENT DISCLOSURE

### Field of the Present Disclosure

The present disclosure relates to a battery state of charge (SOC) prediction apparatus, system, and method, and more particularly, to a technique for accurately predicting a battery state of charge (SOC) value of a vehicle.

### DESCRIPTION OF RELATED ART

Lithium-ion batteries are generally used as batteries for electric vehicle (EV)/Plug-in Hybrid Electric Vehicles (PHEV), and the lithium-ion batteries, which are a type of secondary battery, each include a positive electrode formed of a lithium compound such as NCM, LCO, LFP, and NCA or a mixture thereof, and a negative electrode formed of graphite, silicon, a carbon material, and a mixture thereof. An electrolyte is formed of a mixture of a carbonate (DMC, EC, EMC, etc.) and a carbon compound additive.

These high-voltage batteries for EV/PHEV must operate stably and be able to supply sufficient electric power and driving force to a vehicle, and to the present end, it is essential to accurately estimate and predict a battery state (SOC). Although it is important to accurately estimate a current state of a high-voltage battery in EV/PHEV, in terms of the nature of EV/PHEV, unlike internal combustion engine vehicles, it takes time to charge, and thus in a case of providing path guidance in navigation, a path to a destination via stopping points, charging stations, etc. may be provided, and in the instant case, prediction of battery information at stopping points, charging stations, destinations, etc. is also becoming increasingly important.

Conventionally, the SOC was predicted through a linear comparison with an SOC based on the energy consumed to get to a stopping point, a charging station, a destination, etc., but the SOC value and energy of a vehicle's high-voltage battery are not proportional, and thus an error may increase in a case of being compared linearly. Furthermore, capacity and available energy of the high-voltage battery of the battery vary according to temperature and load (current/power) usage, and thus in a case where an SOC is predicted by applying a simple proportional equation, an error level may become larger.

Furthermore, predicting a battery SOC includes predicting an actual SOC value, a formula for converting a value predicted by the actual SOC to an SOC for display is also complicated according to various situations (charging condition, temperature, etc.), and as the actual SOC value of the battery in which errors occurred is converted to the SOC for the display, an amount of the errors may further increase.

In the present way, in the past, causes of errors in an SOC may overlap so an amount of the errors may become very large.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a battery SOC prediction apparatus, system, and method, configured for increasing prediction accuracy by determining a battery temperature and an electrical load based on the time required to drive to a destination, and predicting the battery SOC in a case where a vehicle arrives at the destination based on vehicle consumed energy, the battery temperature, and the electrical load.

An exemplary embodiment of the present disclosure attempts to provide a battery SOC prediction apparatus, system, and method, configured for providing a final predicted SOC through a process of correcting a first predicted battery SOC by first predicting a battery SOC upon arrival at a destination by estimating an average voltage and a battery consumption capacity, and using an open circuit voltage (OCV), an average load, and a polarization based on a predicted primary battery SOC.

An exemplary embodiment of the present disclosure attempts to provide a battery SOC prediction apparatus, system, and method, configured for reducing an error in a case of converting to an SOC for display by minimizing an error of the battery SOC upon arrival at a destination.

The technical objects of the present disclosure are not limited to the objects mentioned above, and other technical objects not mentioned may be clearly understood by those skilled in the art from the description of the claims.

An exemplary embodiment of the present disclosure provides a battery SOC prediction apparatus including: a processor configured to predict a state of charge (SOC) value of a battery in response to a case where a vehicle arrives at a destination according to energy expected to be consumed while driving to the destination, and in the instant case, to correct the SOC value of the battery upon arrival at the destination according to an electrical load and a battery temperature by predicting the electric load and the battery temperature according to a driving time of the vehicle; and a storage configured to store algorithms and data driven by the processor.

In an exemplary embodiment of the present disclosure, it may further include a communication device configured to receive the energy expected to be consumed while driving to the destination from an in-vehicle controller, to receive a time required to drive to the destination from a navigation, and to receive at least one of a battery voltage, a battery current, a battery temperature, or a combination thereof from a sensing device.

In an exemplary embodiment of the present disclosure, the processor may be configured for estimating a first average voltage using an open circuit voltage (OCV) and a nominal voltage based on a current SOC value of the battery.

In an exemplary embodiment of the present disclosure, the processor may be configured to determine a first consumption capacity of the battery using the first average voltage and the consumed energy.

In an exemplary embodiment of the present disclosure, the processor may be configured to determine a first SOC change of the battery using the first consumption capacity and an initial capacity of the battery.

In an exemplary embodiment of the present disclosure, the processor may be configured for estimating the first arrival SOC in a case where the vehicle arrives at the destination using the first SOC change and the current SOC value of the battery.

In an exemplary embodiment of the present disclosure, the processor may be configured to determine an average OCV value using an OCV determined based on the current SOC value of the battery and an OCV determined based on the first arrival SOC.

In an exemplary embodiment of the present disclosure, the processor may be configured to determine a second consumption capacity of the battery using the average OCV value and the consumed energy.

In an exemplary embodiment of the present disclosure, the processor may be configured to determine an average load, which is an average of the electric load, based on the determined second consumption capacity of the battery and a time required to drive to the destination.

In an exemplary embodiment of the present disclosure, the processor may be configured for estimating a temperature of the battery based on the average load and the time required.

In an exemplary embodiment of the present disclosure, the processor may be configured to determine a polarization, which is a voltage change due to resistance, based on the average load and the temperature of the battery.

In an exemplary embodiment of the present disclosure, the processor may be configured to determine a second average voltage using the polarization and the average OCV value.

In an exemplary embodiment of the present disclosure, the processor may be configured to determine a third consumption capacity of the battery using the determined second average voltage and the consumed energy.

In an exemplary embodiment of the present disclosure, the processor may be configured to determine an SOC change amount of a second battery using the determined third consumption capacity of the battery and the initial capacity of the battery.

In an exemplary embodiment of the present disclosure, the processor may be configured to determine a second arrival SOC upon arrival at the destination using the SOC change amount of the second battery.

In an exemplary embodiment of the present disclosure, the processor may be configured to convert the second arrival SOC into an SOC for display.

In an exemplary embodiment of the present disclosure, the processor may be configured to segment a section to the destination based on at least one of a road type, driving, or an output of a current used, to determine an average load for each section based on a time required for each segmented section, to determine a polarization for each section using the average load for each section, to determine a third consumption capacity using the polarization for each section, to determine an SOC change amount of a second battery for each section using the third consumption capacity for each section, and to determine a second arrival SOC for each section using the SOC change amount of the second battery for each section.

An exemplary embodiment of the present disclosure provides a vehicle system including: a battery SOC prediction apparatus configured to predict a state of charge (SOC) value of a battery in response to a case where a vehicle arrives at a destination according to energy expected to be consumed while driving to the destination, and in the instant case, to correct the SOC value of the battery upon arrival at the destination according to an electrical load and a battery temperature by predicting the electric load and the battery temperature according to a driving time of the vehicle; and an in-vehicle control device configured to provide energy expected to be consumed to drive to the destination to the battery SOC prediction apparatus; and a navigation configured to provide the time required to drive to the destination to the battery SOC prediction apparatus.

An exemplary embodiment of the present disclosure provides a battery SOC prediction method including: predicting, by a processor, a state of charge (SOC) value of a battery in response to a case where a vehicle arrives at a destination according to energy expected to be consumed while driving to the destination; predicting, by the processor, an electric load and a battery temperature according to a driving time of the vehicle; and correcting, by the processor, the SOC value of the battery upon arrival at the destination according to the electrical load and the battery temperature.

In an exemplary embodiment of the present disclosure, the predicting of the SOC value of the battery upon arrival at the destination may include: estimating, by the processor, an average voltage using an open circuit voltage (OCV) and a nominal voltage based on a current SOC value of the battery; determining, by the processor, a consumption capacity of the battery using the average voltage and the consumed energy; and determining, by the processor, an SOC change value of the battery using the consumption capacity and an initial capacity of the battery.

According to an exemplary embodiment of the present disclosure, it may be possible to increase prediction accuracy by predicting a battery SOC in a case where a vehicle arrives at a destination based on vehicle consumed energy, a battery temperature, and an electrical load.

According to an exemplary embodiment of the present disclosure, it may be possible to reduce an error in a case of converting to an SOC for display by minimizing an error of the battery SOC upon arrival at a destination.

Furthermore, various effects which may be directly or indirectly identified through the present specification may be provided.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 illustrates a block diagram showing a configuration of an example vehicle system including a battery SOC prediction apparatus.

FIG. 2 illustrates a block diagram showing a detailed configuration of an example processor of a battery SOC prediction apparatus.

FIG. 3 illustrates a flowchart showing an example battery SOC prediction method.

FIG. 4 illustrates a flowchart showing an example battery SOC prediction method.

FIG. 5 illustrates an example computing system.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, some exemplary embodiments of the present disclosure will be described in detail with reference to exemplary drawings. It should be noted that in adding reference numerals to constituent elements of each drawing, the same constituent elements include the same reference numerals as possible even though they are indicated on different drawings. In describing an exemplary embodiment of the present disclosure, when it is determined that a detailed description of the well-known configuration or function associated with the exemplary embodiment of the present disclosure may obscure the gist of the present disclosure, it will be omitted.

In describing constituent elements according to an exemplary embodiment of the present disclosure, terms such as first, second, A, B, (a), and (b) may be used. These terms are only for distinguishing the constituent elements from other constituent elements, and the nature, sequences, or orders of the constituent elements are not limited by the terms. Furthermore, all terms used herein including technical scientific terms include the same meanings as those which are generally understood by those skilled in the technical field of the present disclosure to which an exemplary embodiment of the present disclosure pertains (those skilled in the art) unless they are differently defined. Terms defined in a generally used dictionary shall be construed to have meanings matching those in the context of a related art, and shall not be construed to have idealized or excessively formal meanings unless they are clearly defined in the present specification.

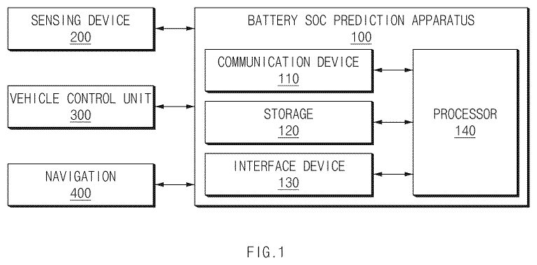

Hereinafter, various exemplary embodiments of the present disclosure will be described in detail with reference to FIG. 1 to FIG. 5.

A battery management system (BMS) technique may include information such as a battery voltage (V), a battery current (A), a battery temperature (C), a battery state of charge (SOC), a battery state of health (SOH), and a battery state of function (SOF), which indicates information related to a current state of a battery. As a BMS becomes more sophisticated, prediction techniques for not only the current state of the battery but also a future state thereof becomes important, and an SOC prediction function presented in an exemplary embodiment of the present disclosure may also be viewed as one of BMS advancement techniques. By upgrading the SOC prediction function, efficient path prediction may be made in response to a case where a customer sets a destination. Furthermore, based on the present technique, it may be used as a base technique to provide customers with various information related to future battery information.

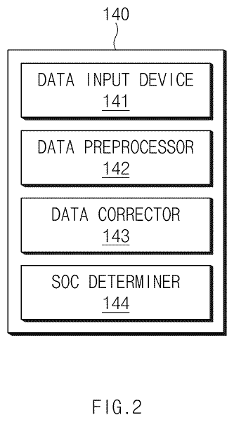

FIG. 1 illustrates a block diagram showing a configuration of an exemplary vehicle system including a battery SOC prediction apparatus, and FIG. 2 illustrates a block diagram showing a detailed configuration of an exemplary processor of a battery SOC prediction apparatus.

Referring to FIG. 1, a vehicle system according to an exemplary embodiment of the present disclosure may include a battery SOC prediction apparatus 100 and a sensing device 200.

The battery SOC prediction apparatus 100 may be configured to predict a state of charge (SOC) value of a battery in response to a case where a vehicle arrives at a destination according to energy expected to be consumed while driving to the destination, and in the instant case, may be configured to correct the SOC value of the battery upon arrival at the destination according to an electrical load and a battery temperature by predicting the electric load and battery temperature according to a driving time of the vehicle, and to increase prediction accuracy by minimizing a prediction error of the SOC value of the battery.

The battery SOC prediction apparatus 100 according to an exemplary embodiment of the present disclosure may be implemented inside or outside the vehicle. In the instant case, the battery SOC prediction apparatus 100 may be integrally formed with internal control units of the vehicle, or may be implemented as a separate hardware device to be connected to control units of the vehicle by a connection means. For example, the battery SOC prediction apparatus 100 may be implemented integrally with the vehicle, may be installed or attached to the vehicle as a configuration separate from the vehicle, or a part thereof may be implemented integrally with the vehicle, and another part may be installed or attached to the vehicle as a configuration separate from the vehicle.

The battery SOC prediction apparatus 100 according to an exemplary embodiment of the present disclosure may be implemented as a BMS.

Referring to FIG. 1, the battery SOC prediction apparatus 100 may include a communication device 110, a storage 120, an interface device 130, and a processor 140. According to an exemplary embodiment of the present disclosure, the battery SOC prediction apparatus 100 may be implemented as a single unit by coupling components with each other, and some components may be omitted.

The communication device 110 is a hardware device implemented with various electronic circuits to transmit and receive signals through a wireless or wired connection, and may transmit and receive information based on in-vehicle devices and in-vehicle network communication techniques. As an exemplary embodiment of the present disclosure, the in-vehicle network communication techniques may include Controller Area Network (CAN) communication, Local Interconnect Network (LIN) communication, flex-ray communication, and the like.

Furthermore, the communication device 110 may perform communication with a server, infrastructure, third vehicles outside the vehicle, and the like through a mobile communication technique, a wireless Internet access technique, or a short range communication technique. The communication device 110 may perform Vehicle-To-Everything (V2X) communication. The V2X communication may include communication between vehicle and all entities such as Vehicle-To-Vehicle (V2V) communication which refers to communication between vehicles, Vehicle-To-Infrastructure (V2I) communication which refers to communication between a vehicle and an eNB or road side unit (RSU), Vehicle-To-Pedestrian (V2P) communication, which refers to communication between user equipment (UE) held by vehicles and individuals (pedestrians, cyclists, vehicle drivers, or occupants), and Vehicle-To-Network (V2N) communication.

The mobile communication technique may include technical standards, communication methods for mobile communication (e.g., Global System for Mobile communication (GSM), Code Division Multi Access (CDMA), Code Division Multi Access 2000 (CDMA 2000), enhanced voice-data optimized or enhanced voice-data only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), 4th generation mobile telecommunication (4G), 5th generation mobile telecommunication (5G)), or the like.

The wireless Internet access technique may include Wireless LAN (WLAN), Wireless-Fidelity (Wi-Fi), Wi-Fi direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), Long Term Evolution-Advanced (LTE-A), etc.

The short-range communication technique may include Bluetooth™, radio frequency identification (RFID), infrared data association (IrDA), ultra wideband (UWB), ZigBee, Near Field Communication (NFC), a wireless universal serial bus (USB) technique, etc.

For example, the communication device 110 may receive information related to energy consumed in response to a case where a vehicle drives to a destination from an in-vehicle control device (e.g., vehicle control unit (VCU) 300), and may receive information such as a time required to drive to the destination from an in-vehicle navigation 400.

Furthermore, the communication device 110 may receive information related to a battery voltage, a battery current, and a battery temperature from the sensing device 200.

The storage 120 may store sensing results and the sensing device 200 and data and/or algorithms required for the processor 140 to operate, and the like.

For example, the storage 120 may store the battery voltage, the battery current, and the battery temperature received from the sensing device 200. Furthermore, the storage 120 may store consumed energy, a time required, etc. received through the communication device 110.

Furthermore, the storage 120 may store information related to an average voltage, capacity consumption, an SOC change, etc. determined by the processor 140. Furthermore, the storage 120 may store information related to an average OCV, an average load, a polarization amount, etc. determined by the processor 140. Furthermore, the storage 120 may store a polarization map for determining the polarization amount, and a temperature model for estimating the battery temperature, etc.

The storage 120 may include a storage medium of at least one type among memories of types such as a flash memory, a hard disk, a micro, a card (e.g., a secure digital (SD) card or an extreme digital (XD) card), a random access memory (RAM), a static RAM (SRAM), a read-only memory (ROM), a programmable ROM (PROM), an electrically erasable PROM (EEPROM), a magnetic memory (MRAM), a magnetic disk, and an optical disk.

The interface device 130 may include an input means for receiving a control command from a user and an output means for outputting an operation state of the apparatus 100 and results thereof. Herein, the input means may include a key button, and may include a mouse, a joystick, a jog shuttle, a stylus pen, and the like. Furthermore, the input means may include a soft key implemented on the display.

For example, the interface device 130 may display the SOC for display.

The interface device 130 may be implemented as a head-up display (HUD), a cluster, an audio video navigation (AVN), or a human machine interface (HM), a human machine interface (HMI).

The output device may include a display, and may also include a voice output means such as a speaker. In the instant case, in a response to a case that a touch sensor formed of a touch film, a touch sheet, or a touch pad is provided on the display, the display may operate as a touch screen, and may be implemented in a form in which an input device and an output device are integrated. In an exemplary embodiment of the present disclosure, the output device may display the battery state of charge (SOC).

In the instant case, the display may include at least one of a liquid crystal display (LCD), a thin film transistor liquid crystal display (TFT LCD), an organic light-emitting diode display (OLED display), a flexible display, a field emission display (FED), and a 3D display.

The processor 140 may be electrically connected to the communication device 110, the storage 120, the interface device 130, and the like, may electrically control each component, and may be an electrical circuit that executes software commands, performing various data processing and determinations described below.

The processor 140 may be configured to process signals transmitted between each component of the battery SOC prediction apparatus 100 and to perform overall control so that each component may normally perform function thereof. The processor 140 may be implemented in a form of hardware, software, or a combination of and software. For example, the processor 140 may be implemented as a microprocessor, but the present disclosure is not limited thereto. For example, it may be, e.g., an electronic control unit (ECU), a micro controller unit (MCU), or other subcontrollers mounted in the vehicle.

The processor 140 may be configured to predict a state of charge (SOC) value of a battery in response to a case where a vehicle arrives at a destination according to energy expected to be consumed while driving to the destination, and in the instant case, may be configured to correct the SOC value of the battery upon arrival at the destination according to an electrical load and a battery temperature by predicting the electric load and the battery temperature according to a driving time of the vehicle.

The processor 140 may be configured for estimating a first average voltage using an open circuit voltage (OCV) and a nominal voltage based on a current SOC value of the battery, to determine a first consumption capacity of the battery using the first average voltage and the consumed energy, and to determine a first SOC change of the battery using the first consumption capacity and an initial capacity of the battery. A difference between the initial capacity of the battery and the first consumption capacity may be the first SOC change. In the instant case, the nominal voltage refers to a voltage value that represents a representative value in a case where a given voltage changes or has tolerance.

However, the processor 140 may be configured to determine an average voltage using an arbitrary voltage other than the OCV or nominal voltage based on a current SOC value of the battery. A purpose of the processor 140 is to obtain an approximate SOC change amount (ASOC) in a data pre-processing section, and thus it may not include a significant effect on an error level of a corresponding logic even in a case where an OCV corresponding to the nominal voltage or the current SOC value of the battery or any voltage similar to the nominal voltage is used.

Furthermore, the processor 140 may be configured to determine the first consumption capacity of the battery by use of the first average voltage and the consumed energy, and to use a different value instead of the consumed energy received from the communication device 110. That is, in a case of a battery, the voltage decreases as an SOC decreases, and even with the same ASOC value, higher energy has higher energy. Accordingly, even though the consumed energy is the same, considering the current SOC value, it is possible to modify it by giving more weight and correction in a case where the SOC is low.

Accordingly, the processor 140 may be configured for estimating a first arrival SOC in a case where the vehicle arrives at the destination using the first SOC change and the current SOC value of the battery. That is, the first arrival SOC may be determined by subtracting the SOC change value of the first battery from the current SOC value of the battery.

The processor 140 may be configured to determine an average OCV value using the OCV determined based on the current SOC value of the battery and the OCV determined based on a previously estimated first arrival SOC.

In the instant case, the processor 140 may be configured to determine the voltage value based on a slope in an SOC-OCV curve instead of an average of the OCV based on the current SOC value and the OCV based on the first arrival SOC value, and to use an average plus or minus a small correction value as the voltage value instead of the average of the OCV.

The processor 140 may be configured to determine a second consumption capacity of the battery using a previously determined average OCV value and the consumed energy received by the communication device 110. That is, the processor 140 may be configured to determine the second consumption capacity of the battery by dividing the consumed energy by the average OCV value.

The processor 140 may be configured to determine an average load, which is an average of the electric load, based on the second consumption capacity of the battery and the time required to drive to the destination. That is, the processor 140 may be configured to determine the average load by dividing the determined consumption capacity by the time required. In the instant case, the average load may include battery voltage consumption by convenience devices that consume battery voltage, such as an air conditioner, while the vehicle is driving. Accordingly, the voltage of the battery varies according to the load, while driving, as the load increases, the battery voltage decreases, and in a case where the load is large in the same SOC value, the voltage becomes lower and the available energy becomes less. Accordingly, SOC prediction accuracy may be increased by predicting SOC by reflecting the electric load.

Furthermore, the processor 140 may be configured to determine the average load using a time required for each section rather than a total time required to drive to the destination. For example, the processor 140 may be configured to divide a section to the destination into sections based on a type of road (ex. city road/highway), a driving speed (ex. low/medium/high speed, etc.), a current/output used (low output/high output), etc., and may be configured to determine the average load based on a time required for each section. In the present way, in a case of determining the average load by segmenting it by section rather than the total time required, SOC prediction determination accuracy may be further increased.

The processor 140 may be configured for estimating a temperature of the battery based on the average load and the time required. In the instant case, the processor 140 may be configured for estimating the temperature by reflecting the average load and the time required in a pre-stored temperature model.

The processor 140 may be configured to determine a polarization, which is a voltage change due to resistance, based on the average load and the temperature of the battery. In the instant case, the processor 140 may be configured to use the battery temperature estimated based on the temperature model or the battery temperature received from the sensing device 200. That is, the processor 140 may be configured to determine the polarization based on the average load and the battery temperature. In the instant case, the processor 140 may be configured to determine the polarization for each section using the average load for each section described above. Accordingly, the processor 140 may increase the SOC prediction accuracy by determining the polarization in detail for each section.

The processor 140 may be configured to determine a second average voltage using the polarization and the average OCV value. In the instant case, the processor 140 may be configured to determine the second average voltage for each section using the polarization amount for each section described above. Accordingly, the processor 140 may increase SOC prediction accuracy by determining the second average voltage divided by section.

The processor 140 may be configured to determine a third consumption capacity of the battery using the determined second average voltage and consumed energy. In the instant case, the processor 140 may be configured to determine the third consumption capacity for each section using the second average voltage for each section described above. Accordingly, the processor 140 may increase SOC prediction accuracy by determining the third consumption capacity divided by section.

The processor 140 may be configured to determine an SOC change amount of a second battery using the determined third consumption capacity of the battery and an initial capacity of the battery. In the instant case, the processor 140 may be configured to determine the SOC change amount of the second battery for each section using the third consumption capacity for each section described above. Accordingly, the processor 140 may increase SOC prediction accuracy by determining the SOC change amount of the second battery divided by section.

The processor 140 may be configured to determine a second arrival SOC upon arrival at the destination using the determined SOC change amount of the second battery.

The processor 140 may be configured to convert the determined second arrival SOC into an SOC for display.

The sensing device 200 may be configured to detect a battery current, a battery voltage, and a battery temperature, and to the present end, may include a current sensor, a voltage sensor, and a temperature sensor.

Referring to FIG. 2, the processor 140 may include a data input device 141, a data preprocessor 142, a data corrector 143, and an SOC determiner 144.

In an exemplary embodiment of the present disclosure, the data input device 141, the data preprocessor 142, the data corrector 143, and the SOC determiner 144 may be configured by one or more processors, or an integrated single processor.

The data input device 141 may receive information inputted through the sensing device 200 and the communication device 110. For example, battery current information, battery voltage information, battery temperature information, etc. may be input thereto.

The data preprocessor 142 may preprocess information inputted through the data input device 141. The data preprocessor 142 may be configured for estimating a first average voltage using an open circuit voltage (OCV) and a nominal voltage based on a current SOC value of the battery, to determine a first consumption capacity of the battery using the first average voltage and consumed energy, and to determine the first SOC change of the battery using the first consumption capacity and an initial capacity of the battery. Accordingly, the data preprocessor 142 may be configured for estimating the first arrival SOC in a case where the vehicle arrives at the destination using the first SOC change and the current SOC value of the battery. The data preprocessor 142 does not know the arrival SOC value, and thus an average voltage may be estimated using the current SOC value and the nominal voltage, but after preprocessing, an average OCV may be determined based on an approximate arrival SOC.

The data corrector 143 may be configured to determine an average OCV value using the OCV determined based on the current SOC value of the battery and the OCV determined based on the first arrival SOC value, and may be configured to determine the second consumption capacity of the battery using the average OCV value and the consumed energy.

Furthermore, the data corrector 143 may be configured to determine the average load, which is an average of the electric load, based on the determined second consumption capacity of the battery and the time required to drive to the destination, may estimate a temperature of the battery based on the average load and the time required, may be configured to determine a polarization, which is a change in voltage due to resistance, based on the average load and the temperature of the battery.

Furthermore, the data corrector 143 may be configured to determine the second average voltage using the polarization and the average OCV value, and may be configured to determine the third consumption capacity of the battery using the second average voltage and the consumed energy.

The SOC determiner 144 may be configured to determine an SOC change amount of the second battery using the third consumption capacity of the battery and the initial capacity of the battery, and may be configured to determine the second arrival SOC upon arrival at the destination using the SOC change amount of the second battery.

Furthermore, the SOC determiner 144 may convert the determined second arrival SOC into an SOC for display.

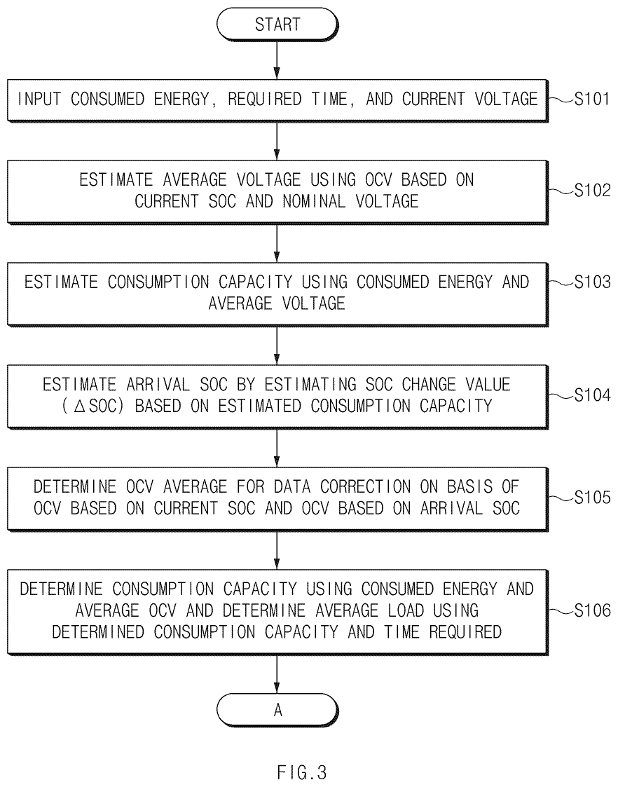

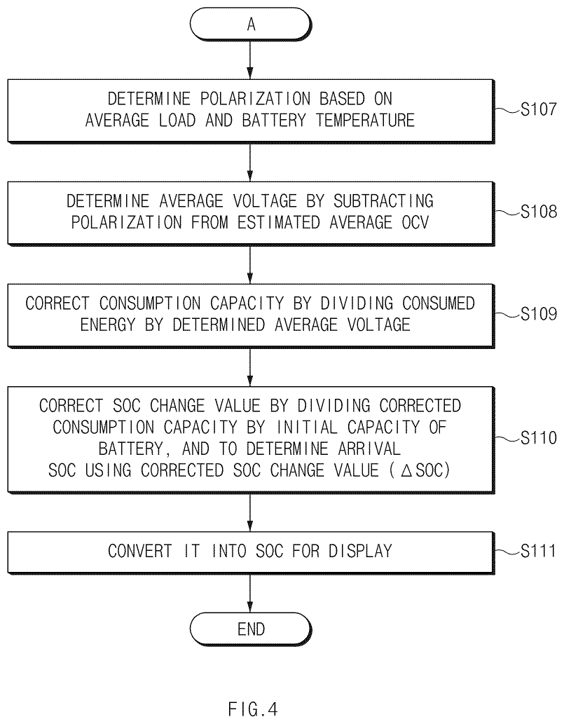

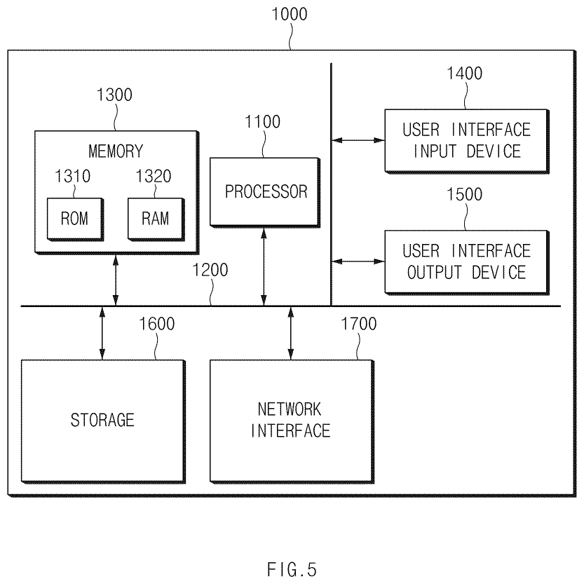

Hereinafter, a battery SOC prediction method according to an exemplary embodiment of the present disclosure will be described with reference to FIG. 3 and FIG. 4. FIG. 3 and FIG. 5 each illustrate a flowchart showing an example battery SOC prediction method.

Hereinafter, it is assumed that the battery SOC prediction apparatus 100 of the of FIG. 1 performs processes of FIG. 5. Furthermore, in the description of FIG. 5, operations referred to as being performed by a device may be understood as being controlled by the processor 140 of the battery SOC prediction apparatus 100. In following exemplary embodiments of the present disclosure, operations of steps S101 to S111 may be performed sequentially, but are not necessarily performed sequentially. For example, an order of each operation may be changed, and at least two operations may be performed in parallel.

Referring to FIG. 3, the battery SOC prediction apparatus 100 may be configured to receive a consumed energy value, a required time, a current SOC value, and a current battery voltage. In the instant case, the battery SOC prediction apparatus 100 may be configured to receive the consumed energy value and the time required to reach the destination from the navigation 400 and the current battery voltage from the sensing device 200 (S101).

The battery SOC prediction apparatus 100 may be configured for estimating the average voltage using an OCV based on the current SOC value and the nominal voltage (S102). In the instant case, the nominal voltage may be stored in advance in the storage 120. Furthermore, the OCV based on the current SOC may be determined in real time by the battery SOC prediction apparatus 100.

The battery SOC prediction apparatus 100 may be configured for estimating consumption capacity using consumed energy and an average voltage (S103). In the instant case, the consumed energy may be received from the navigation 400, and the average voltage may be a value estimated in step S102. It also refers to the consumption capacity of the battery. The consumed energy may be a value which may be obtained by multiplying consumption capacity by a voltage change value, and the voltage may vary according to a change in SOC area, a temperature change, and an acceleration.

Subsequently, the battery SOC prediction apparatus 100 may be configured for estimating the SOC change amount using the consumption capacity estimated in step S103, and may estimate the arrival SOC using the estimated SOC change amount (S104). In the instant case, the SOC refers to a ratio according to the consumption capacity.

The above-described steps S102 to S104 may be performed by the data preprocessor 142 of FIG. 2, and the data preprocessor 142 may estimate the arrival SOC through steps S102 to S104.

Subsequently, the battery SOC prediction apparatus 100 may be configured to determine an average OCV for data correction based on the OCV based on the current SOC value and the OCV based on the arrival SOC (S105).

The battery SOC prediction apparatus 100 may be configured to determine the consumption capacity using the consumed energy and the average OCV determined in step S105, and to determine an average load using the determined consumption capacity and the time required (S106). The battery SOC prediction apparatus 100 may be configured to determine the consumption capacity by dividing the consumed energy by the average OCV, and may be configured to determine the average load by dividing the determined consumption capacity by the time required. In the instant case, the battery SOC prediction apparatus 100 may be configured to receive the consumed energy and the time required from the navigation system 400 or another in-vehicle controller. A voltage of the battery may vary according to the load, in response to a case where the vehicle is driving, and as the load increases, the battery voltage may decrease. Accordingly, in response to a case where the load is large in the same SOC value, the voltage may become lower, and thus the available energy may also become smaller. Accordingly, it may be desirable to consider the load in a case of predicting the SOC value of the battery.

Accordingly, referring to FIG. 4, the battery SOC prediction apparatus 100 may be configured to determine a polarization based on the average load and a battery temperature (S107). In the instant case, the battery SOC prediction apparatus 100 may be configured to predict the battery temperature based on the average load and the time required by utilizing a temperature model.

The battery SOC prediction apparatus 100 may be configured to determine the polarization based on the average load and the battery temperature (S107). In the instant case, the polarization is a voltage change amount due to resistance. In the instant case, the battery SOC prediction apparatus 100 may be configured to store and use a polarization map for determining the polarization in advance.

The average OCV determined in step S105 is determined based on a case where the load is 0, and thus the battery SOC prediction apparatus 100 may be configured to determine the average voltage based on the polarization determined in step S107 (S108).

The battery SOC prediction apparatus 100 may be configured to correct the consumption capacity by dividing the consumed energy by the average voltage determined in step S105 to determine the consumption capacity (S109).

The battery SOC prediction device 100 may be configured to correct an SOC change value by dividing the corrected consumption capacity by an initial capacity of the battery, and to determine the arrival SOC using the corrected SOC change value (ASOC) (S110). In the instant case, the battery SOC prediction apparatus 100 may be configured to correct an SOC conversion value by dividing the consumption capacity determined in step S109 by the initial capacity and then multiplying by 100 to determine the SOC conversion value.

The battery SOC prediction apparatus 100 may be configured to convert the arrival SOC into a display SOC to provide it to the display. In the instant case, a logic that converts the arrival SOC into the display SOC may be used to convert the arrival SOC into the display SOC value, and the present logic may be stored in advance.

In the present way, according to an exemplary embodiment of the present disclosure, it may be possible to more accurately perform SOC prediction at the destination or transit point of eco-friendly vehicles such as EV/PHEV by predicting the SOC in consideration of not only available energy but also load and battery temperature.

Accordingly, according to an exemplary embodiment of the present disclosure, through accurate SOC prediction, while driving to the destination, it may be possible to accurately provide users with information such as whether charging is needed, the number of times charging is needed, and remaining SOC information, and user convenience may be increased by including a charging station as a waypoint and informing the user about whether charging is necessary based on the remaining SOC in a case of performing route guidance or re-departing from the destination.

FIG. 5 illustrates an example computing system.

Referring to FIG. 5, the computing system 1000 includes at least one processor 1100 connected through a bus 1200, a memory 1300, a user interface input device 1400, a user interface output device 1500, and a storage 1600, and a network interface 1700.

The processor 1100 may be a central processing unit (CPU) or a semiconductor device which is configured to perform processing on commands stored in the memory 1300 and/or the storage 1600. The memory 1300 and the storage 1600 may include various types of volatile or nonvolatile storage media. For example, the memory 1300 may include a read only memory (ROM) 1310 and a random access memory (RAM) 1320.

Accordingly, steps of a method or algorithm described in connection with the exemplary embodiments included herein may be directly implemented by hardware, a software module, or a combination of the two, executed by the processor 1100. The software module may reside in a storage medium (i.e., the memory 1300 and/or the storage 1600) such as a RAM memory, a flash memory, a ROM memory, an EPROM memory, an EEPROM memory, a register, a hard disk, a removable disk, and a CD-ROM.

An exemplary storage medium is coupled to the processor 1100, which can read information from and write information to the storage medium. Alternatively, the storage medium may be integrated with the processor 1100. The processor and the storage medium may reside within an application specific integrated circuit (ASIC). The ASIC may reside within a user terminal. Alternatively, the processor and the storage medium may reside as separate components within the user terminal.

The above description is merely illustrative of the technical idea of the present disclosure, and those skilled in the art to which the present disclosure pertains may make various modifications and variations without departing from the essential characteristics of the present disclosure.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Software implementations may include software components (or elements), object-oriented software components, class components, task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well-known to a person including ordinary knowledge in the art.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, a plurality of operations may be merged, or any operation may be divided, and a predetermined operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A battery state of charge (SOC) prediction apparatus comprising:
a processor configured to predict a state of charge (SOC) value of a battery in response to a case where a vehicle arrives at a destination according to energy expected to be consumed while driving to the destination, and to correct the SOC value of the battery upon arrival at the destination according to an electrical load and a battery temperature by predicting the electric load and the battery temperature according to a driving time of the vehicle; and
a storage configured to store algorithms and data driven by the processor.

2. The battery SOC prediction apparatus of claim 1, further including a communication device configured:
to receive information related to the energy expected to be consumed while driving to the destination from an in-vehicle controller,
to receive information related to a time required to drive to the destination from a navigation, and
to receive information related to at least one of a battery voltage, a battery current, a battery temperature, or a combination thereof from a sensing device.

3. The battery SOC prediction apparatus of claim 1, wherein the processor is further configured for estimating a first average voltage using an open circuit voltage (OCV) and a nominal voltage based on a current SOC value of the battery.

4. The battery SOC prediction apparatus of claim 3, wherein the processor is further configured to determine a first consumption capacity of the battery using the first average voltage and the consumed energy.

5. The battery SOC prediction apparatus of claim 4, wherein the processor is further configured to determine a first SOC change of the battery using the first consumption capacity and an initial capacity of the battery.

6. The battery SOC prediction apparatus of claim 5, wherein the processor is further configured for estimating the first arrival SOC in a case where the vehicle arrives at the destination using the first SOC change and the current SOC value of the battery.

7. The battery SOC prediction apparatus of claim 6, wherein the processor is further configured to determine an average OCV value using the OCV determined based on the current SOC value of the battery and an OCV determined based on the first arrival SOC.

8. The battery SOC prediction apparatus of claim 7, wherein the processor is further configured to determine a second consumption capacity of the battery using the average OCV value and the consumed energy.

9. The battery SOC prediction apparatus of claim 8, wherein the processor is further configured to determine an average load, which is an average of the electric load, based on the determined second consumption capacity of the battery and a time required to drive to the destination.

10. The battery SOC prediction apparatus of claim 9, wherein the processor is further configured for estimating a temperature of the battery based on the average load and the time required to drive to the destination.

11. The battery SOC prediction apparatus of claim 10, wherein the processor is further configured to determine a polarization, which is a voltage change due to resistance, based on the average load and the temperature of the battery.

12. The battery SOC prediction apparatus of claim 11, wherein the processor is further configured to determine a second average voltage using the polarization and the average OCV value.

13. The battery SOC prediction apparatus of claim 12, wherein the processor is further configured to determine a third consumption capacity of the battery using the determined second average voltage and the consumed energy.

14. The battery SOC prediction apparatus of claim 13, wherein the processor is further configured to determine an SOC change amount of a second battery using the determined third consumption capacity of the battery and the initial capacity of the battery.

15. The battery SOC prediction apparatus of claim 14, wherein the processor is further configured to determine a second arrival SOC upon arrival at the destination using the SOC change amount of the second battery.

16. The battery SOC prediction apparatus of claim 15, wherein
the processor is further configured to convert the second arrival SOC into an SOC for display.

17. The battery SOC prediction apparatus of claim 8, wherein the processor is further configured:
to segment a section to the destination based on at least one of a road type, driving, or an output of a current used,
to determine an average load for each section based on a time required for each segmented section,
to determine a polarization for each section using the average load for each section,
to determine a third consumption capacity using the polarization for each section, to determine an SOC change amount of a second battery for each section using the third consumption capacity for each section, and
to determine a second arrival SOC for each section using the SOC change amount of the second battery for each section.

18. A vehicle system comprising:
a battery SOC prediction apparatus configured to predict a state of charge (SOC) value of a battery in response to a case where a vehicle arrives at a destination according to energy expected to be consumed while driving to the destination, and to correct the SOC value of the battery upon arrival at the destination according to an electrical load and a battery temperature by predicting the electric load and the battery temperature according to a driving time of the vehicle; and
an in-vehicle control device configured to provide energy expected to be consumed to drive to the destination to the battery SOC prediction apparatus; and
a navigation configured to provide a time required to drive to the destination to the battery SOC prediction apparatus.

19. A battery SOC prediction method comprising:
predicting, by a processor, a state of charge (SOC) value of a battery in response to a case where a vehicle arrives at a destination according to energy expected to be consumed while driving to the destination;
predicting, by the processor, an electric load and a battery temperature according to a driving time of the vehicle; and
correcting, by the processor, the SOC value of the battery upon arrival at the destination according to the electrical load and the battery temperature.

20. The battery SOC prediction method of claim 19, wherein the predicting of the SOC value of the battery upon arrival at the destination includes:
estimating, by the processor, an average voltage using an open circuit voltage (OCV) and a nominal voltage based on a current SOC value of the battery;
determining, by the processor, a consumption capacity of the battery using the average voltage and the consumed energy; and
determining, by the processor, an SOC change value of the battery using the consumption capacity and an initial capacity of the battery.
